(19) United States
(12) Patent Application Publication
(10) Pub. No.: US 2006/0233968 A1
(43) Pub. Date: Oct. 19, 2006

(54) System and method for vaporizing a metal

(76) Inventors: Tihiro Ohkawa, La Jolla, CA (US); Karl R. Umstadter, San Diego, CA (US)

Correspondence Address: NEIL K. NYDEGGER;NYDEGGER & ASSOCIATES, 348 Olive Street, San Diego, CA, 92103, US

(21) Appl. No.: 11/109,137

(22) Filed: Apr. 19, 2005

(51) Int. Cl. B05D 3/00; C23C 8/00; C23C 16/00

(52) U.S. Cl. 427/561; 427/585; 118/726

(57) ABSTRACT

A laser device for vaporizing a metal requires a source for generating a laser beam having a predetermined power density at a point on the laser beam. A solid metal target material is then moved along a path, and through the point, relative to the laser beam. This is done to sequentially transition the target material from a solid to a liquid, and from a liquid to a vapor. In this process there is minimal liquid ejection.

### FIELD OF THE INVENTION

The present invention pertains generally to systems and methods for using a laser to vaporize materials. More particularly, the present invention pertains to systems and methods for using lasers to vaporize metals and metal compounds. The present invention is particularly, but not exclusively, useful for creating a metal vapor in a vapor jet production process, while minimizing the ejection of liquid material from the process before it can be vaporized.

### BACKGROUND OF THE INVENTION

Metal vapors can be useful for many industrial purposes, such as in vapor deposition procedures. For example, such procedures may be particularly applicable where it is desirable to achieve a substantially uniform metallic coating on a substrate. In any event, and for whatever reason, whenever a metal vapor is being generated, it is generally desirable that the vapor has certain determinable characteristics or attributes. For one, it may be desirable that there be very little, if any, ionization in the metal vapor. In particular, this attribute is desirable in applications where the resultant metal vapor is to be subjected to a magnetic field. For another, it is desirable that as much of the target material as possible be actually vaporized.

An important consideration for the creation of a metal vapor involves the selection of a system that can be used to effectively vaporize the metal. For some applications, the use of an oven may be appropriate. Ovens, however, can be cumbersome and allow for uneven vapor jet production of the target material. This is particularly so if it is mixed or heterogeneous. For this reason, among others, various irradiation systems have been suggested as an alternative to ovens.

Commercially available microwave radiation is known to be capable of generating the heat loads that are required to vaporize metals. The electric field that is associated with microwave radiation, however, induces an ionization of the metal vapor that in some applications may cause a reflection of the microwave radiation before it reaches the target. This, of course, will reduce the efficiency of the system. Laser radiation, however, is also known to be effective for the purpose of vaporizing metals. Importantly, laser irradiance and wavelength can be controlled to minimize ionization of the resultant vapor.

In addition to the selection of a heating source, a critically important factor for consideration when using a metal to create a vapor is the target material itself. Specifically, for such a process, vaporization temperatures (Tᵥ) above 3500° K are typically required. Of particular concern here is the fact that when a metal target is heated for vaporization, it will transition from a solid to a liquid, and then from liquid to a gas (vapor). Also, because metals normally have melting point temperatures (Tₘ) that are more than one thousand degrees Kelvin below their vaporization temperature (Tᵥ>>Tₘ), and because they have relatively high coefficients of thermal conductivity (κ) for both their solid and liquid phases, the liquid phase needs to be reckoned with. In particular, there will likely be a significant amount of target material in the liquid phase. The important consequence here is that, for an efficient metal vaporization process, the loss of liquid droplets needs to be minimized.

With the above in mind, when considered in terms of throughput, (Γ), a metal vaporization process can be expressed as:
Γₛ=Γₗ+Γᵥ [eqn. 1]
where Γₛ is the solid throughput, Γₗ is the liquid throughput, and Γᵥ is the vapor throughput. In the optimal case for metal vaporization, all of the metal is vaporized and Γₗ=0. Further, to keep the evaporating surface stationary, it is necessary that:
nₛu=nᵥvᵥ [eqn. 2]
where “nₛ” and “nᵥ” are the respective number densities of the solid metal and metal vapor, “u” is the feed velocity of the solid metal, and “Vᵥ” is the vapor velocity.

As a practical matter, during a metal vaporization process, Γₗ may not equal zero. An important reason for this is that the vapor pressure, pᵥ, generates substantial forces on the liquid phase of the material as the metal is vaporized. These forces may then cause droplets to be ejected from the liquid before they can be vaporized. When this happens, the ejected droplets constitute the liquid throughput, Γₗ. Consequently, as the liquid throughput (Γₗ) increases, the overall efficiency of the vapor jet production process is diminished.

For an appreciation of several factors that are involved in the vaporization of a metal, consider the one-dimensional case wherein the metal target material is formed as a cylindrical rod having a radius “a”. Further, consider the target material is being axially advanced along a path at the feeding velocity “u”, and through a point on the path where a heating device (e.g. a laser beam) generates a determinable vaporization power density (Hnᵥvᵥ). In this expression for power density, H is the heat of vapor jet production per atom. Due to the power density of the heating source, the target material will sequentially transition from a solid to a liquid, and from the liquid to a gas (vapor). During these transitions, the melt zone where the target material is in its liquid phase will have a depth “d”. It happens that this depth “d” is related to characteristics of the vapor by the expression:
d=κ/(3nᵥvᵥk) [eqn. 3]
wherein “κ” is thermal conductivity of the metal, and “k” is the Boltzmann constant.

In the one-dimensional case, the vapor pressure (pᵥ) pushes against the liquid metal with an axially directed force that tends to eject liquid droplets from the melt zone. Specifically, this ejection of liquid droplets from the melt zone occurs before the droplets can be vaporized and will generally be in a radial direction. Droplet ejection, however, is resisted by forces that are generated in the liquid due to; 1) surface tension; 2) inertia; and 3) viscosity. Conditions for “d” (i.e. the depth of the melt zone), wherein these resistive forces minimize droplet ejection, can be respectively expressed as:
d<χ/pᵥ [eqn. 4]
where “χ” is the surface tension of the liquid;
d<Mnₛu²a/pᵥ [eqn. 5]
for a condition where “M” is the mass of the atom, and wherein the radial velocity of the liquid due to inertia is less than the feed velocity “u” of the target material; and
d²<ηau/pᵥ [eqn. 6]
where the viscosity of the liquid is influenced by the liquid/solid interface in the metal target material.

It can be shown that if any one of the conditions set forth in eqns. 4, 5 or 6 above is satisfied, the loss of liquid droplets from the target feed material will be minimized. Accordingly, plots of the respective expressions (eqns. 4, 5 and 6) are set forth in FIG. 1 as a function of the vapor throughput characteristics nᵥvᵥ.

A comparative evaluation of the plots for zirconium is presented in FIG. 1 to indicate that inertial conditions in the liquid phase of the metal target material will allow for an increase in “d” with an increase in the product of vapor characteristics nᵥvᵥ, under certain conditions. Thus, by combining eqn. 3 with eqn. 5, an expression for the number density (nᵥ) of a useable vapor can be obtained. The obtained value for nᵥ can then be used to determine an appropriate power density for the heating source. With the above in mind, the expression for the number density (nᵥ), derived by combining eqns. 3 and 5, is:
nᵥ>[κnₛ/3kvᵥa]^{1/2} [eqn. 7]

And, the expression for the power density required for vaporization becomes
Hnᵥvᵥ=H[κnₛv_{v/}3ka]^{1/2} [eqn. 8]

In light of the above, it is an object of the present invention to provide a system and method for vaporizing a metal with a laser beam that minimizes liquid losses during the creation of the vapor. Another object of the present invention is to provide a system and method for vaporizing a metal with a laser beam that avoids ionization of the resultant vapor. Still another object of the present invention is to provide a system and method for vaporizing a metal that is simple to use, is relatively easy to manufacture, and is comparatively cost effective.

### SUMMARY OF THE INVENTION

In accordance with the present invention, a device for vaporizing a solid metal target material includes a source for generating a laser beam, and an optical apparatus for directing the beam along a beam path. Specifically, the laser beam is generated to establish a predetermined power density over an area at a predetermined point (i.e. focal point) on the beam path. Preferably, this predetermined power density will be in a range between approximately ten gigawatts per square meter and about one hundred gigawatts per square meter (10-100 GW/m²). With this in mind, the area at the point on the laser beam where this power density is generated will be less than a square millimeter (area≦1 mm²) and will, typically, be around one half square millimeter.

Insofar as the solid metal target itself is concerned, it can either be a pure metal or a metal compound. Further, the target metal can be formed as a brick (i.e. block) with a substantially flat surface, or it can be formed as a cylindrical rod. In the latter case, the cross sectional area of the rod will be approximately the same as the point on the beam path where the laser power density is measured (e.g. cross sectional area<1 mm²).

In the operation of the present invention, the target material is somehow moved relative to the laser beam, or vice versa with a velocity “u”. In each case the purpose is to sequentially transition the target material from a solid to a liquid, and from a liquid to a vapor. In this transition, the liquid portion (i.e. liquid phase) of the target material is maintained at a substantially constant depth “d”. Preferably, this depth is on the order of a few microns (d<10 μm).

In specific cases where the target material is formed as a cylindrical rod, the optical apparatus holds the laser beam stationary while directing the laser beam to the target material. The rod is then advanced along a laser path and through the point on the laser beam where the desired laser power density is being generated. There the target material is vaporized. In the case where the target material is formed as a block having a substantially flat surface, the point on the laser beam where the desired laser power density is being generated is maintained coincident with the surface of the target material. In this latter case, the optical means also moves the point on the laser beam over the surface of the target material. Preferably, this movement is made along a Lissajous' curve.

For the specific case wherein the target material is a cylindrical rod having a radius “a”, as the disclosure above in the BACKGROUND OF THE INVENTION indicates, eqn. 5 is controlling. With reference to eqn. 5, FIG. 1 then shows an operable region between the melt thickness that is attainable for a given laser power, (i.e. “d”) and the inertial forces in the molten target material that resist a so-called “splatter” of the target material. Within this operable region, the practical limitation for a vapor jet production process is the feed velocity “u” that can be sustained.

As intended for the present invention, vaporization of the target metal creates a vapor with a throughput in a range between approximately one one-tenth of a mole per second and one mole per second (0.1-1 mole/sec). Importantly, adjustments in the power density level of the laser beam is selected to minimize the creation of any liquid throughput (i.e. avoid liquid splatter), and to avoid creating a plasma from the vapor.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a graph comparing exemplary data for melt layer thickness and vapor throughput for a vapor jet production process in accordance with the present invention;

FIG. 2 is a perspective view of a device in accordance with the present invention, with portions broken away for clarity;

FIG. 3 is a side, elevation view of a rod-like, cylindrical-shaped target metal material for use with the embodiment shown in FIG. 2;

FIG. 4 is a perspective view of an alternate embodiment of the present invention, shown with an optical steering mechanism, and with portions broken away for clarity; and

FIG. 5 is a cross sectional view of the target metal material as seen along the line 5-5 in FIG. 4.

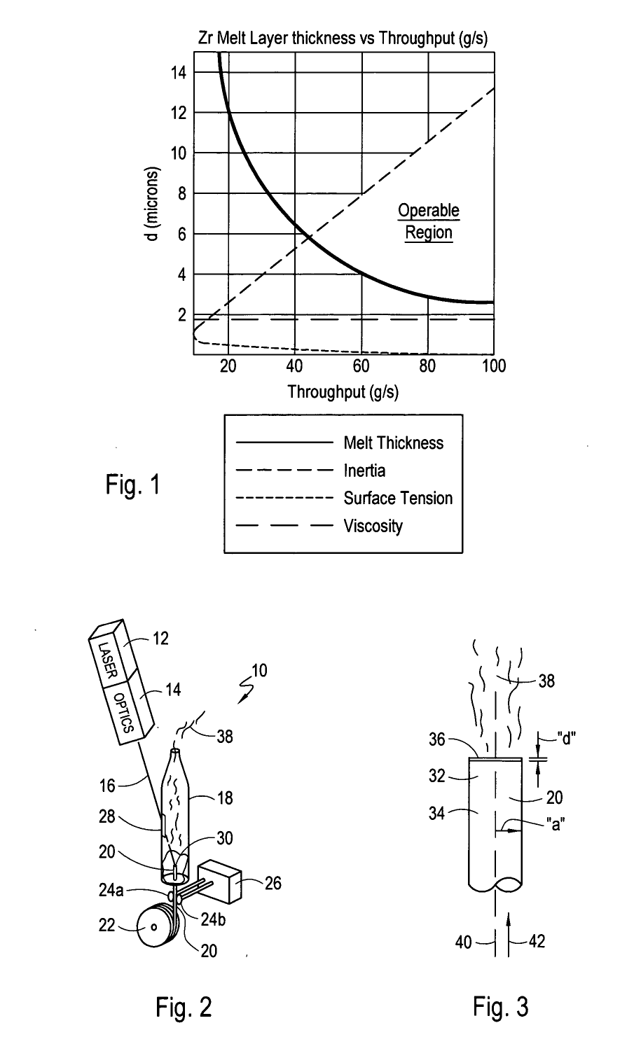

### DESCRIPTION OF THE PREFERRED EMBODIMENTS

Referring initially to FIG. 2, a device for vaporizing a metal in accordance with the present invention is shown, and is generally designated 10. As shown, the device 10 includes a laser source 12 which is coupled with appropriate optics 14. Specifically, the laser source 12 can be of any type well known in the pertinent art that is capable of generating a continuous laser beam 16. Further, the optics 14 can be of any type well known in the pertinent art that is capable of focusing the laser beam to a focal spot with a power density that is in a range of about ten to one hundred gigawatts per square meter (10-100 GW/m²).

FIG. 2 also shows that the device 10 includes a vessel 18 which receives a metal target material 20 for vaporization. For the embodiment of the present invention shown in FIG. 2, the metal target material 20 is substantially cylindrical shaped and has a radius “a” (see FIG. 3). Further, FIG. 2 shows that the metal target material 20 is supplied from a reel 22, and is advanced into the vessel 18 by counter-rotating feed rollers 24a and 24b. To do this, the feed rollers 24a,b are simultaneously counter-rotated by a drive unit 26. For the present invention, the metal target material 20 can be any metal or metal compound.

Still referring to FIG. 2, it is seen that the optics 14 of the device 10 direct the laser beam 16 from the laser source 12, through a window 28 in the vessel 18. Further, the laser beam 16 is focused by the optics 16 to a point 30 inside the vessel 18. Importantly, the laser beam 16 is focused to a focal spot at the point 30 that has an area which is substantially the same as the area of the exposed end 32 (see FIG. 3) of the cylindrical shaped metal target material 20 (i.e. area=πa²). For most applications, the area of the focal spot (i.e. πa²) will be less than one square millimeter and, typically, will be around one half square millimeter (πa²=0.5 mm²). Recall, the power density over this area will be in an approximate range between ten and one hundred gigawatts per square meter (10-100 GW/m²).

For purposes of the present invention, it is to be appreciated that the metal target material 20 will inherently have a relatively high thermal conductivity. This characteristic of the metal target material 20 will cause it to successively progress through three noticeably different phases within the vessel 18. As shown in FIG. 3, these are: a solid phase 34, a liquid phase 36, and a vapor (gas) phase 38. As discussed above, however, it is desirable that little, if any, of the target material 20 be lost during the liquid phase (i.e. liquid throughput is preferably zero: Γ₁=0). Stated differently, it is desirable that the vapor throughput, Γᵥ, be equal to the solid throughput, Γₛ (i.e. Γᵥ=Γₛ). To this end, the metal target material 20 is fed through the point 30 in vessel 18 along a path 40 in the direction of arrow 42 at a feed velocity “u”.

As the metal target material 20 is being fed into the vessel 18 for vaporization, several aspects of the process are particularly important. For one, it is desirable that the metal target material 20 be advanced (fed) into the vessel 18 with a sustainable velocity. With this in mind, the feed velocity “u” and the power density (Hnᵥvᵥ: see eqn. 8) of the laser beam 16 at the point 30 need to be reconciled in view of eqn. 5: namely, d<Mnₛu²a/pᵥ where pᵥ=kTᵥnᵥ. In this context, care should be taken to ensure that the vapor 38 will not be ionized by the laser beam 16. Another important aspect of the vaporization process is that, if there is any liquid throughput (Γₗ), the particulates of this throughput should have diameters as small as possible and, preferably, less than about one micron. Regardless of the value of “d”, however, an optimal condition for vaporization is realized whenever the vapor throughput equals the solid throughput (Γᵥ=Γₛ).

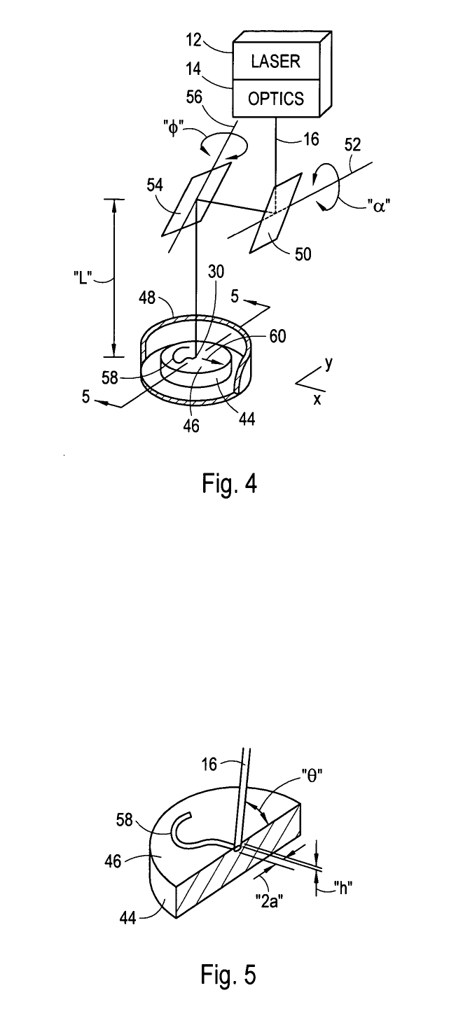

FIG. 4 shows an alternate embodiment for the device 10 of the present invention wherein the metal target material is formed as a brick (block) 44. As shown, the brick 44 is formed with a substantially flat surface 46 and is positioned in a protective receptacle 48 for vaporization. Similar to the embodiment discussed above with reference to FIGS. 2 and 3, for the alternate embodiment, the laser beam 16 is also focused to a focal spot at the point 30. Again, the power density over the area at point 30 will be in an approximate range between ten and one hundred gigawatts per square meter (10-100 GW/m²). For the alternate embodiment, however, it is necessary that the point 30 of laser beam 16 be somehow moved over the surface 46 to vaporize the metal target material of brick 44. Alternatively, the point 30 can be held stationary while the brick 44 is moved.

As indicated in FIG. 4, a steering mechanism can be provided for movement of the point 30 of laser beam 16. Specifically, this mechanism may include a mirror 50 that is positioned for rotation around an axis 52 through an angle “α”. The mechanism may also include a mirror 54 that is positioned for rotation around an axis 56 through an angle “φ”. Further, as shown, the mirror 54 is effectively positioned at a distance “L” above the surface 46 of the metal target material brick 44. In this combination the axis 52 is oriented perpendicular to the axis 56. Consequently, independent rotations of the mirrors 50 and 54 will respectively result in movements of the point 30 on surface 46 in “x” and “y” directions. For purposes of the present invention, the mirrors 50 and 54 can be of any type well known in the pertinent art, such as galvanometric or piezoelectric mirrors.

For the vaporization of metal target material in brick 44, the point 30 of laser beam 16 is moved over the surface 46 along a curve 58. More specifically, the point 30 is moved along curve 58 with a linear velocity “w” and in a variable direction that, for purposes of disclosure, is indicated by the arrow 60. Preferably, the curve 58 is a Lissajous' curve. Further, it will be appreciated that the result of this movement is a vaporization of metal target material on the surface 46 that forms a trench having a depth “h” and a width “2a” (see FIG. 5). With this in mind, and referring to FIG. 5, various geometrical relationships that are pertinent to the movement of the point 30 can be determined. In general, using approximations, the variables “w”, “L”, “h”, “a”, “θ”, “φ”, and “α” can be used to describe both dimensional and dynamic relationships for the device 10. In this context, it can be dimensionally shown that: tan θ=u/w=h/a. Dynamically, it can be shown that: d(φ; α)/dt=W/L. Using these relationships, it is possible to manipulate the mirrors 50 and 54 to appropriately move the point 30 of laser beam 16 for the selected power density. Importantly, as with other embodiments of the present invention, it is desirable to minimize any liquid throughput (i.e. material loss due to particulate ejection) and to avoid ionizing the resultant vapor 38. It will be appreciated that the optics 14 for this embodiment of the present invention can either be positioned as shown in FIG. 4, or the optics 14 can be appropriately positioned on the path of laser beam 16 between the mirrors 50, 54 and the brick 44.

While the particular System and Method for Vaporizing a Metal as herein shown and disclosed in detail is fully capable of obtaining the objects and providing the advantages herein before stated, it is to be understood that it is merely illustrative of the presently preferred embodiments of the invention and that no limitations are intended to the details of construction or design herein shown other than as described in the appended claims.

What is claimed is:

1. A device for vaporizing a metal, which comprises:
a laser source for generating a laser beam, wherein the laser beam has a predetermined power density over an area (πa²) at a point on the laser beam;
a solid metal target material; and
a mechanical means for moving the target material relative to the laser beam at a velocity “u” along a path and through the area (πa²) at the point on the laser beam to sequentially transition the target material from a solid to a liquid, and from a liquid to a vapor as the target material passes through the area, wherein the liquid target material is maintained at a substantially constant depth “d” while satisfying the condition d<Mnₛu²a/pᵥ, wherein M is the mass of an atom of target material, nₛ is the number density of the target material and pᵥ is the vapor pressure of the vapor.

2. A device as recited in claim 1 wherein the substantially constant depth “d” of the liquid target material is on the order of five microns (d≅5 μm).

3. A device as recited in claim 1 wherein the predetermined power density is approximately 60 GW/m².

4. A device as recited in claim 1 wherein the vapor is created with a throughput in a range between approximately one tenth of a mole per second and one mole per second (0.1-1 mole/sec).

5. A device as recited in claim 1 wherein the target material is substantially cylindrical shaped and the area (πa²) is a cross sectional area of the cylindrical target material.

6. A device as recited in claim 5 wherein the cross sectional area of the target material is substantially the same as the area at the point on the laser beam.

7. A device as recited in claim 6 wherein the area at the point on the laser beam is approximately equal to less than one square millimeter (area≦1 mm²).

8. A device as recited in claim 1 wherein the metal target material is block shaped and has a substantially flat surface, and wherein the area at the point on the laser beam is coincident with the surface of the target material.

9. A device as recited in claim 8 further comprising an optical means for moving the area at the point on the laser beam along a Lissajous' curve on the surface of the target material.

10. A device for vaporizing a metal, which comprises:
a solid metal target material having a substantially flat surface;
a means for directing a laser beam onto an area (πa²) at a point on the surface of the metal target material with a predetermined power density, to sequentially transition the target material in the area (πa²) from a solid to a liquid, and from a liquid to a vapor; and
a means for moving the metal target material relative to the laser beam at a velocity “u” to maintain the liquid target material at a substantially constant depth “d” within the area while satisfying the condition d<Mnₛu²a/pᵥ, wherein M is the mass of an atom of target material, nₛ is the number density of the target material and pᵥ is the vapor pressure of the vapor.

11. A device as recited in claim 10 wherein the substantially constant depth “d” of the liquid target material is on the order of five microns (d≅5 μm) and wherein the predetermined power density is approximately 60 GW/m².

12. A device as recited in claim 10 wherein the vapor is created with a throughput in a range between approximately one tenth of a mole per second and one mole per second (0.1-1 mole/sec).

13. A device as recited in claim 10 wherein the target material is substantially cylindrical shaped and has a cross sectional area substantially the same as the area at the point on the surface.

14. A device as recited in claim 13 wherein the area at the point on the surface is approximately equal to less than one square millimeter (area≦1 mm²).

15. A device as recited in claim 10 wherein the metal target material is block shaped and the device further comprises an optical means for moving the area at the point on the surface of the target material along a Lissajous' curve.

16. A device as recited in claim 15 wherein the optical means includes a pair of piezoelectric mirrors.

17. A method for vaporizing a solid metal target material, which comprises the steps of:
generating a laser beam, wherein the laser beam has a predetermined power density over an area (πa²) at a point on the laser beam; and
moving the target material relative to the laser beam along a path and through the area (πa²) at the point on the laser beam at a velocity “u” to sequentially transition the target material from a solid to a liquid, and from a liquid to a vapor as the target material passes through the area, wherein the liquid target material is maintained at a substantially constant depth “d” along the path while satisfying the condition d<Mnₛu²a/pᵥ, wherein M is the mass of an atom of target material, nₛ is the number density of the target material and pᵥ is the vapor pressure of the vapor.

18. A method as recited in claim 17 wherein the substantially constant depth “d” of the liquid target material is on the order of five microns (d≅5 μm) and the predetermined power density of the laser beam is approximately 60 GW/m².

19. A method as recited in claim 17 wherein the vapor is created with a throughput in a range between approximately one tenth of a mole per second and one mole per second (0.1-1 mole/sec), wherein the target material is substantially cylindrical shaped and has a cross sectional area, and further wherein the cross sectional area of the target material is substantially the same as the area at the point on the laser beam.

20. A method as recited in claim 17 wherein the metal target material is block shaped and has a substantially flat surface, and wherein the area at the point on the laser beam is coincident with the surface of the target material, and further wherein the moving step requires moving the area at the point on the laser beam along a Lissajous' curve on the surface of the target material.
